(19) United States
(12) Patent Application Publication
(10) Pub. No.: US 2009/0231825 A1
(43) Pub. Date: Sep. 17, 2009

(54) ELECTROMAGNETIC SHIELDING DEVICE

(75) Inventors: Kuan-Hsing LI, Taichung City (TW); Chih-Hsien CHIU, Changhua City (TW)

Correspondence Address: DUANE MORRIS LLP - Philadelphia;IP DEPARTMENT, 30 SOUTH 17TH STREET, PHILADELPHIA, PA, 19103-4196, US

(73) Assignee: UNIVERSAL SCIENTIFIC INDUSTRIAL CO., LTD., Tsao-Tun Chen (TW)

(21) Appl. No.: 12/048,333

(22) Filed: Mar. 14, 2008

(51) Int. Cl. H05K 9/00

(52) U.S. Cl. 361/818

(57) ABSTRACT

An electromagnetic shielding device includes a base board mounted with an electronic component on a top surface thereof and having a looped surrounding surface interconnecting the top surface and a bottom surface. The surrounding surface has an inclined upper surface portion extending outwardly and downwardly from a periphery of the top surface and attached with a looped solder pad. A metal cover is mounted on the base board, and has a looped surrounding wall extending downwardly from a periphery of a top wall. The surrounding wall has a bottom end connected electrically and fixedly to the solder pad such that the metal cover cooperates with the base board to define an inner receiving space therebetween for receiving the electronic component.

### BACKGROUND OF THE INVENTION

1. Field of the Invention

The invention relates to an electromagnetic shielding device.

2. Description of the Related Art

FIG. 1 illustrates an electronic device employing a conventional electromagnetic shielding device that includes a circuit board 1 and a metal cover 2. The circuit board 1 has a component-mounting surface 101 mounted with a plurality of electronic components 102, and a looped solder pad 103 attached to the component-mounting surface 101 and disposed to surround the electronic components 102. The metal cover 2 is mounted on the circuit board 1 using surface mounting techniques, and has a top wall 201, and a looped surrounding wall 202 connected integrally to a periphery of the top wall 201. The surrounding wall 202 has one end connected electrically and fixedly to the solder pad 103. It is noted that the solder pad 103 is disposed so that there is preferably a distance (w) between the electronic components 102 and a looped inner surface of the surrounding wall 202 of the metal cover 2.

However, in order to attach fully the solder pad 103 to the component-mounting surface 101, a looped peripheral region 104 of the component-mounting surface 101 is preferably maintained between the solder pad 103 and a periphery of the circuit board 1 such that a distance (w1) is formed between a looped outer surface of the surrounding wall 202 of the metal cover 2 and the periphery of the circuit board 1. As a result, the circuit board 1 has a relatively large size, thereby impeding miniaturization of the electronic device.

### SUMMARY OF THE INVENTION

Therefore, the object of the present invention is to provide an electromagnetic shielding device that can overcome the aforesaid drawbacks of the prior art.

According to one aspect of the present invention, there is provided an electromagnetic shielding device that comprises:

a base board having a top surface adapted to be mounted with an electronic component thereon, a bottom surface opposite to the top surface and having an area larger than that of the top surface, and a looped surrounding surface interconnecting peripheries of the top and bottom surfaces, the looped surrounding surface having an inclined upper surface portion extending outwardly and downwardly from the periphery of the top surface;

a looped solder pad attached to the inclined upper surface portion of the looped surrounding surface of the base board; and

a metal cover mounted on the base board, and having a top wall, and a looped surrounding wall extending downwardly from a periphery of the top wall, the looped surrounding wall having a bottom end connected electrically and fixedly to the looped solder pad such that the metal cover cooperates with the base board so as to define an inner receiving space therebetween for receiving the electronic component.

According to another aspect of the present invention, there is provided an electromagnetic shielding device that comprises:

a base board having a top surface adapted to be mounted with an electronic component thereon, a bottom surface opposite to the top surface and having an area larger than that of the top surface, and a looped surrounding surface interconnecting peripheries of the top and bottom surfaces, the looped surrounding surface having a vertical upper surface portion extending downwardly from the periphery of the top surface, a vertical lower surface portion extending upwardly from the periphery of the bottom surface, and a horizontal intermediate surface portion interconnecting a lower end of the vertical upper surface portion and an upper end of the vertical lower surface portion;

a looped solder pad attached to the vertical upper surface portion and the horizontal intermediate surface portion of the looped surrounding surface of the base board; and

a metal cover mounted on the base board, and having a top wall, and a looped surrounding wall extending downwardly from a periphery of the top wall and connected electrically and fixedly to the looped solder pad such that the metal cover cooperates with the base board so as to define an inner receiving space therebetween for receiving the electronic component.

### BRIEF DESCRIPTION OF THE DRAWINGS

Other features and advantages of the present invention will become apparent in the following detailed description of the preferred embodiments with reference to the accompanying drawings, of which:

FIG. 1 is a schematic sectional view of an electronic device employing a conventional electromagnetic shielding device;

FIG. 2 is a schematic sectional view showing an electronic device employing the first preferred embodiment of an electromagnetic shielding device according to the present invention;

FIG. 3a to 3c are perspective views illustrating how the electronic device is fabricated;

FIG. 4 is a schematic sectional view illustrating a final step of fabricating the electronic device; and

FIG. 5 is a schematic sectional view showing an electronic device employing the second preferred embodiment of an electromagnetic shielding device according to the present invention.

### DETAILED DESCRIPTION OF THE PREFERRED EMBODIMENTS

Before the present invention is described in greater detail, it should be noted that like elements are denoted by the same reference numerals throughout the disclosure.

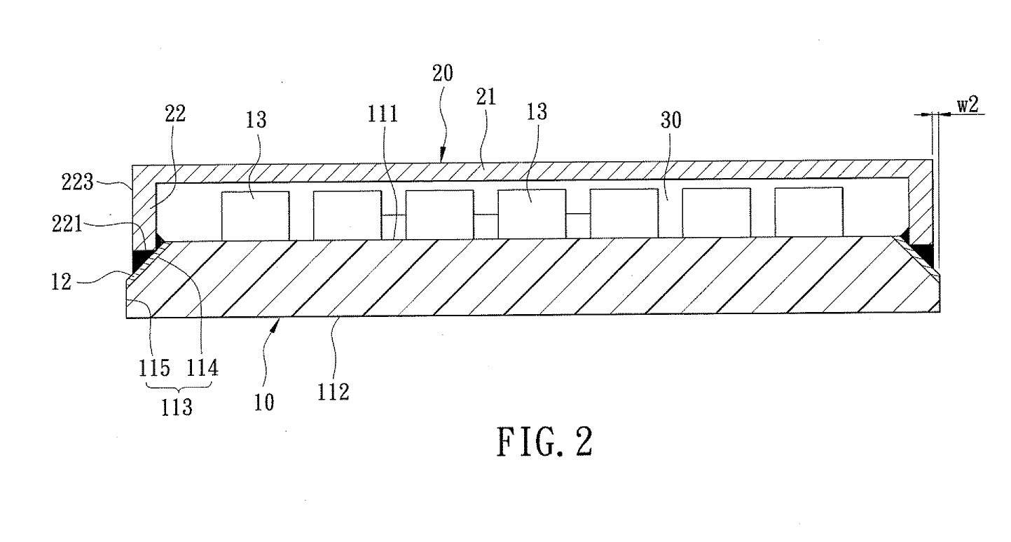

Referring to FIG. 2, the first preferred embodiment of an electromagnetic shielding device according to the present invention is shown to be embodied in an electronic device, such as a wireless communication electronic device. The electromagnetic shielding device includes a base board 10, a looped solder pad 12, and a metal cover 20.

The base board 10, such as a rectangular circuit board, has a top surface 111 adapted to be mounted with a plurality of electronic components 13 of the electronic device thereon, a bottom surface 112 opposite to the top surface 111 and having an area larger than that of the top surface 111, and a looped surrounding surface 113 interconnecting peripheries of the top and bottom surfaces 111, 112. In this embodiment, the looped surrounding surface 113 has an inclined upper surface portion 114 extending outwardly and downwardly from the periphery of the top surface 111, and an upright lower surface portion 115 having an upper end connected to a lower end of the inclined upper surface portion 114.

The looped solder pad 12 is attached to the inclined upper surface portion 114 of the looped surrounding surface 113 of the base board 10 by plating techniques.

The metal cover 20 is mounted on the base board 10 using surface mounting techniques, and has a top wall 21, and a looped surrounding wall 22 extending downwardly from a periphery of the top wall 21. The looped surrounding wall 22 has a bottom end 221 connected electrically and fixedly to the looped solder pad 12 such that the metal cover 20 cooperates with the base board 10 so as to define an inner receiving space therebetween for receiving the electronic components 13.

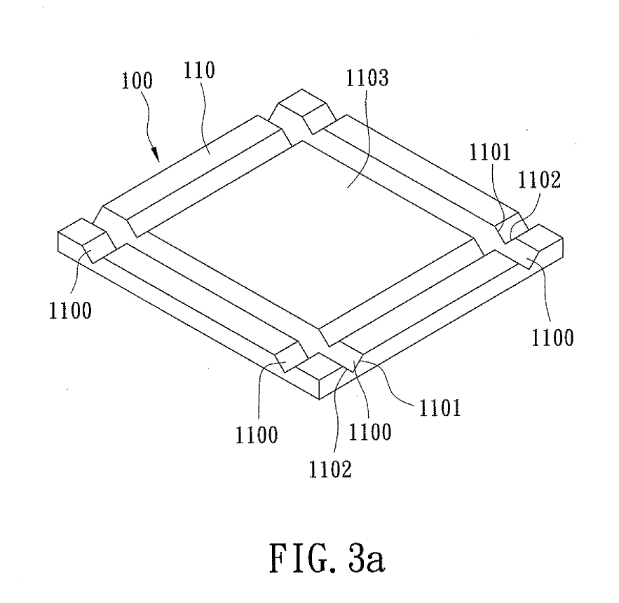

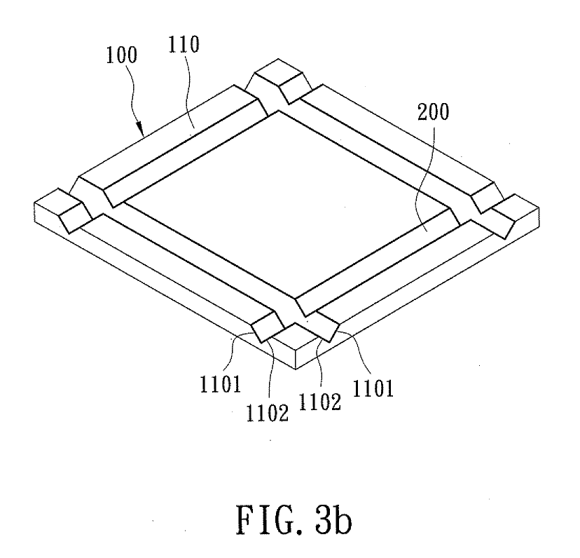

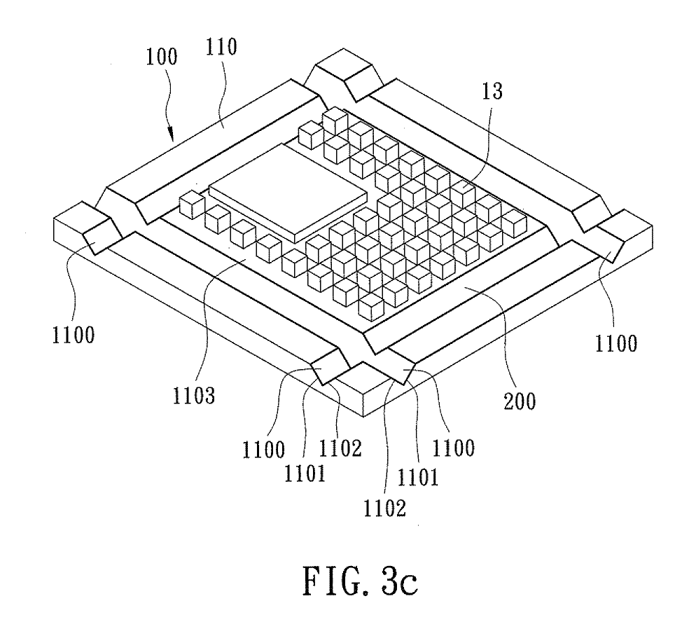

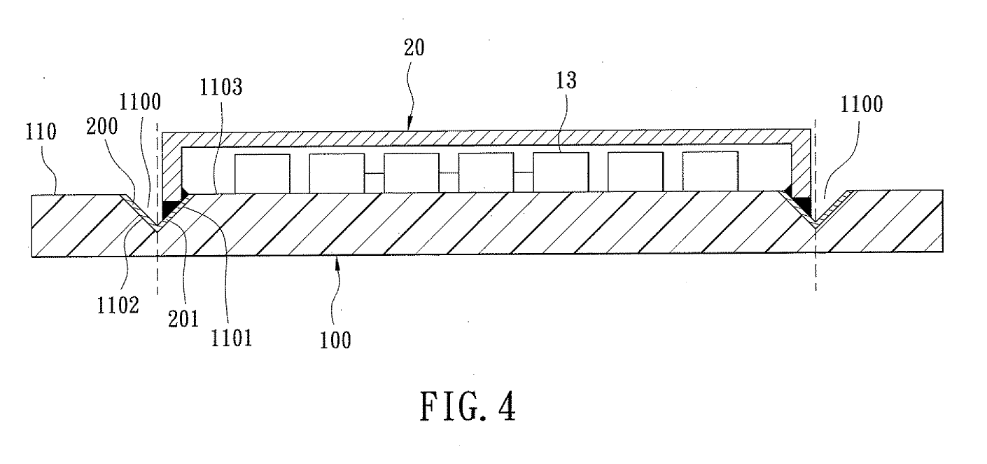

FIGS. 3a, 3b, 3c and 4 illustrate how the electronic device employing the electromagnetic shielding device of the first preferred embodiment is fabricated. Firstly, a rectangular substrate 100 is provided, wherein the substrate 100 has a top surface 110 formed with four open-ended slots 1100 having a V-shaped cross-section. The slots 1100 are respectively adjacent to and parallel to four sides of the substrate 100. Each slot 1100 is defined by first and second flat surfaces 1101, 1102 opposite to each other, as shown in FIG. 3a. It is noted that a central portion 1103 of the top surface 110 of the substrate 100 defined among the four slots 1100 serves as the top surface 111 of the base board 10 of FIG. 2. Central portions of the first flat surfaces 1101 of the substrate 100 constitute the inclined upper surface portion 114 of the looped surrounding surface 113 of the base board 10 of FIG. 2. Then, a solder material 200 is plated on the first and second flat surfaces 1101, 1102 of the substrate 100, as shown in FIG. 3b. It is noted that the solder material 200 plated on the portions of the first flat surfaces 1101 of the substrate 100 constitutes the looped solder pad 12 of FIG. 2. Subsequently, the electronic components 13 are mounted on the central portion 1103 of the top surface 110 of the substrate 100 (see FIG. 3c). Thereafter, the metal cover 20 is covered over the portion 1103 of the top surface 110 of the substrate 100, and is mounted on the substrate 100 using surface mounting techniques, as shown in FIG. 4. Finally, an unnecessary peripheral portion of the substrate 100 is cut off such that the electronic device is completed.

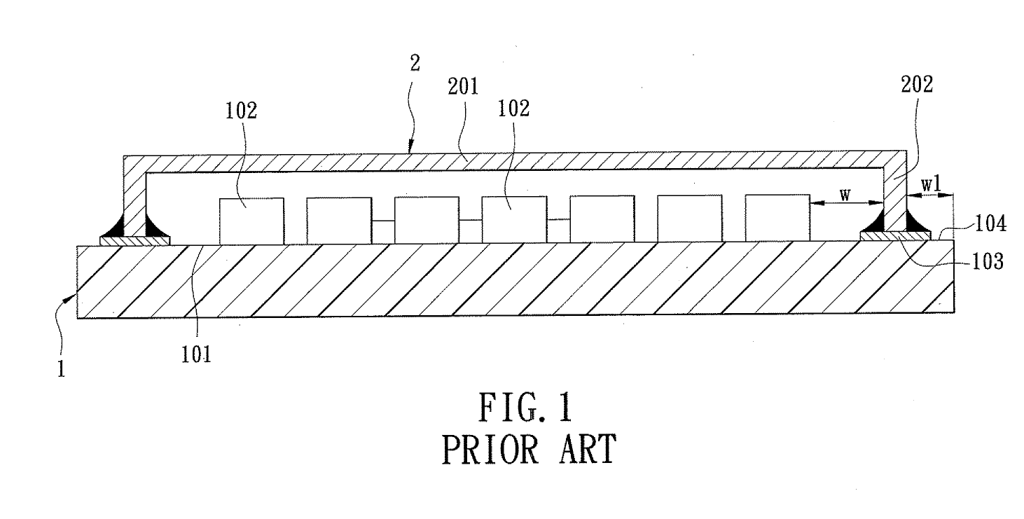

In such a configuration, the solder pad 12 is attached to the inclined upper surface portion 114 of the looped surrounding surface 113 of the base board 10 without requiring the looped peripheral region 104 present in the aforesaid conventional electromagnetic shielding device of FIG. 1. In addition, a distance (w2) (see FIG. 2) between a looped outer surface 223 of the surrounding wall 22 of the metal cover 20 and the upright lower surface portion 115 of the looped surrounding surface 113 of the base board 10 is much less than the distance (w1) in FIG. 1. As a result, the base board 10 has a relatively small size, thereby facilitating miniaturization of the electronic device. Furthermore, due to the presence of the inclined upper surface portion 114, the metal cover 20 can be accurately positioned on the base board 10 during assembly.

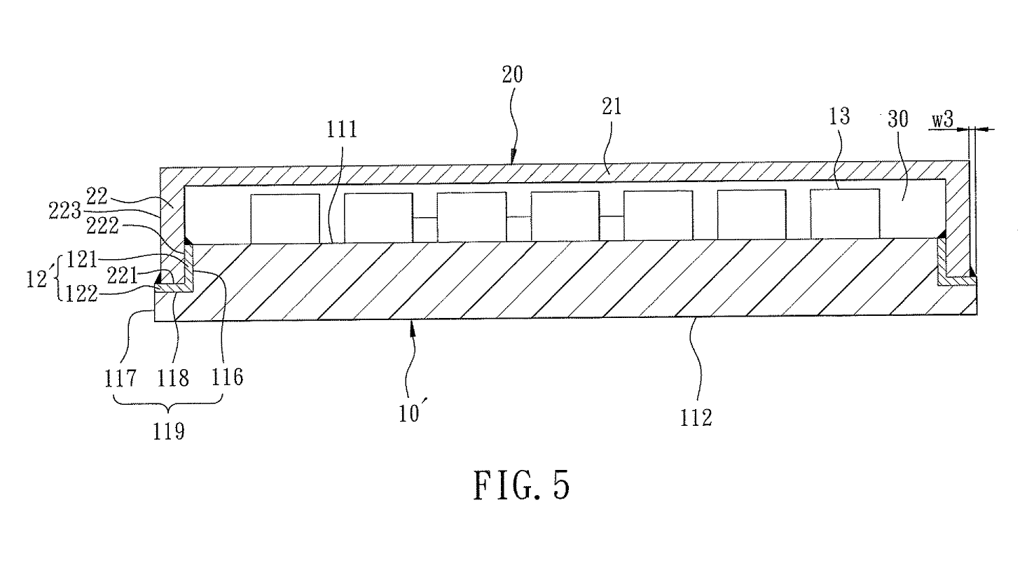

FIG. 5 illustrates the second preferred embodiment of an electromagnetic shielding device according to this invention, which is a modification of the first preferred embodiment. In this embodiment, the looped surrounding surface 119 of the base board 10′ has a vertical upper surface portion 116 extending downwardly from the periphery of the top surface 111, a vertical lower surface portion 117 extending upwardly from the periphery of the bottom surface 112, and a horizontal intermediate surface portion 118 interconnecting a lower end of the vertical upper surface portion 116 and an upper end of the vertical lower surface portion 117.

In addition, the looped solder pad 12′ has a vertical pad portion 121 attached to the vertical upper surface portion 116 of the looped surrounding surface 119 of the base board 10′, and a horizontal pad portion 122 connected to a lower end of the vertical pad portion 121 and attached to the horizontal intermediate surface portion 118 of the looped surrounding surface 119 of the base board 10′. As a result, the bottom end 221 of the looped surrounding wall 22 of the metal cover 20 is in electrical contact with the horizontal pad portion 122 of the looped solder pad 12′. The looped surrounding wall 22 of the metal cover 20 further has a looped inner surface 222 in electrical contact with the vertical pad portion 121 of the looped solder pad 12′.

In such a configuration, the solder pad 12′ is attached to the vertical upper surface portion 116 and the horizontal intermediate surface portion 118 of the looped surrounding surface 119 of the base board 10′ without requiring the looped peripheral region 104 present in the aforesaid conventional electromagnetic shielding device of FIG. 1. In addition, a distance (w3) between the looped outer surface 223 of the looped surrounding wall 22 of the metal cover 20 and the vertical lower surface portion 117 of the looped surrounding surface 119 of the base board 10′ is much less than the distance (w1) in FIG. 1. As a result, the base board 10′ has a relatively small size, thereby facilitating miniaturization of the electronic device. Furthermore, due to the presence of the vertical upper surface portion 116 and the horizontal intermediate surface portion 118, the metal cover 20 can be accurately positioned on the base board 10′ during assembly.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

We claim:

1. An electromagnetic shielding device comprising:
a base board having a top surface adapted to be mounted with an electronic component thereon, a bottom surface opposite to said top surface and having an area larger than that of said top surface, and a looped surrounding surface interconnecting peripheries of said top and bottom surfaces, said looped surrounding surface having an inclined upper surface portion extending outwardly and downwardly from said periphery of said top surface;
a looped solder pad attached to said inclined upper surface portion of said looped surrounding surface of said base board; and
a metal cover mounted on said base board, and having a top wall, and a looped surrounding wall extending downwardly from a periphery of said top wall, said looped surrounding wall having a bottom end connected electrically and fixedly to said looped solder pad such that said metal cover cooperates with said base board so as to define an inner receiving space therebetween for receiving the electronic component.

2. The electromagnetic shielding device as claimed in claim 1, wherein said looped surrounding surface of said base board further has an upright lower surface portion having an upper end connected to a lower end of said inclined upper surface portion.

3. An electromagnetic shielding device comprising:
a base board having a top surface adapted to be mounted with an electronic component thereon, a bottom surface opposite to said top surface and having an area larger than that of said top surface, and a looped surrounding surface interconnecting peripheries of said top and bottom surfaces, said looped surrounding surface having a vertical upper surface portion extending downwardly from said periphery of said top surface, a vertical lower surface portion extending upwardly from said periphery of said bottom surface, and a horizontal intermediate surface portion interconnecting a lower end of said vertical upper surface portion and an upper end of said vertical lower surface portion;
a looped solder pad attached to said vertical upper surface portion and said horizontal intermediate surface portion of said looped surrounding surface of said base board; and
a metal cover mounted on said base board, and having a top wall, and a looped surrounding wall extending downwardly from a periphery of said top wall and connected electrically and fixedly to said looped solder pad such that said metal cover cooperates with said base board so as to define an inner receiving space therebetween for receiving the electronic component.

4. The electromagnetic shielding device as claimed in claim 3, wherein:
said looped solder pad has a vertical pad portion attached to said vertical upper surface portion of said looped surrounding surface of said base board, and a horizontal pad portion connected to a lower end of said vertical pad portion and attached to said horizontal intermediate surface portion of said looped surrounding surface of said base board; and
said looped surrounding wall of said metal cover has a looped inner surface in electrical contact with said vertical pad portion of said looped solder pad, and a bottom end in electrical contact with said horizontal pad portion of said looped solder pad.
